(19) United States
(12) Patent Application Publication
(10) Pub. No.: US 2019/0213380 A1
(43) Pub. Date: Jul. 11, 2019

(54) OPTICAL FINGERPRINT RECOGNITION SENSOR

(71) Applicant: ELECTRONICS AND TELECOMMUNICATIONS RESEARCH INSTITUTE, Daejeon (KR)

(72) Inventors: Chul Woong JOO, Daejeon (KR); Jonghee LEE, Daejeon (KR); Jae-Eun PI, Daejeon (KR); Byoung-Hwa KWON, Daejeon (KR); Hyunsu CHO, Daejeon (KR); Seung Youl KANG, Daejeon (KR); Seongdeok AHN, Daejeon (KR); Jeong Ik LEE, Daejeon (KR); Nam Sung CHO, Daejeon (KR); Sung Haeng CHO, Cheongju (KR); Woojin SUNG, Sejong (KR); Jongchan LEE, Seoul (KR)

(21) Appl. No.: 16/219,373

(22) Filed: Dec. 13, 2018

(30) Foreign Application Priority Data
Jan. 8, 2018 (KR) 10-2018-0002433

(51) Int. Cl. G06K 9/00

(52) U.S. Cl. CPC G06K 9/0004; H01L 51/5237

(57) ABSTRACT

Provided is an optical fingerprint recognition sensor. The optical fingerprint recognition sensor includes a transparent light emitting unit configured to emit light to a fingerprint, a light receiving unit disposed below the light emitting unit to vertically overlap the light emitting unit and configured to receive light reflected by the fingerprint, and a control unit disposed below the light emitting unit to vertically overlap the light emitting unit and configured to control the light emitting unit and the light receiving unit. The light emitting unit includes an organic layer.

### CROSS-REFERENCE TO RELATED APPLICATIONS

This U.S. non-provisional patent application claims priority under 35 U.S.C. § 119 of Korean Patent Application No. 10-2018-0002433, filed on Jan. 8, 2018, the entire contents of which are hereby incorporated by reference.

### BACKGROUND

The present disclosure herein relates to an optical fingerprint recognition sensor, and more particularly, to an optical fingerprint recognition sensor in which a control unit and a light receiving unit vertically overlap a light emitting unit.

A fingerprint recognition technology is a technology for recognizing users by acquiring digital images of fingerprints using dedicated sensors. A fingerprint recognition sensor uses an ‘optical manner’ in which one module constituted by a light emitting unit emitting light to an LED or an OLED and a light receiving unit receiving the light is disposed in a sensor to scan brightness recognized by each module and a ‘capacitive manner’ of reading a voltage by a fine difference in current due to a curve of a fingerprint.

In recent years, a fingerprint recognition sensor technology using the optical manner has a disadvantage that it needs to maintain a certain area due to opaque characteristics based on silicon. To solve this disadvantage, recently, a transparent fingerprint recognition sensor technology has been attracting attention, but the following technical limitations need to be solved for realization. First, technologies for manufacturing and arraying a transparent light emitting device and a selective light receiving device capable of producing current at a specific wavelength are required. Second, optical design and device manufacturing technologies for selectively receiving only light reflected by a ridge and a valley of the fingerprint are required. Third, a light receiving device and an optical design, which are capable of receiving light having a wavelength or intensity at which the light is transmitted through translucent devices, are required.

### SUMMARY

The present disclosure provides a fingerprint recognition sensor having high integration and resolution.

The present disclosure also provides a fingerprint recognition sensor having high resolution by reducing interference of light reflected from a ridge and a valley.

An embodiment of the inventive concept provides an optical fingerprint recognition sensor including: a transparent light emitting unit configured to emit light to a fingerprint; a light receiving unit disposed below the light emitting unit to vertically overlap the light emitting unit and configured to receive light reflected by the fingerprint; and a control unit disposed below the light emitting unit to vertically overlap the light emitting unit and configured to control the light emitting unit and the light receiving unit, wherein the light emitting unit includes an organic layer.

In an embodiment, the light emitting unit may further include: a metal thin film layer on the organic layer; a capping layer on the metal thin film layer; and a reflection layer on the capping layer, wherein the capping layer may have a thickness greater than that of the reflection layer.

In an embodiment, light emitted from the organic layer may be repeatedly reflected between the metal thin film layer and the reflection layer.

In an embodiment, the reflection layer may include silver (Ag).

In an embodiment, the reflection layer may have a thickness of about 15 nm to about 20 nm, and the capping layer may have a thickness of about 10 nm to about 1 μm.

In an embodiment, the light emitting unit may further include: a first electrode below the organic layer; and a second electrode on the organic layer, wherein the second electrode may include the metal thin film layer.

In an embodiment, the light emitting unit may further include a plurality of encapsulation layers, and the encapsulation layer having a low refractive index and the encapsulation layer having a high refractive index may be alternately laminated.

In an embodiment, the light receiving unit may receive light reflected by a ridge of the fingerprint.

In an embodiment, the light receiving unit may be provided in plurality, and the plurality of light receiving units may receive light reflected by a ridge of the fingerprint and light reflected by a valley of the fingerprint, respectively.

In an embodiment, each of the second electrode and the metal thin film layer may be transparent.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1A is a schematic plan view of an optical fingerprint recognition sensor according to a comparative example of the inventive concept;

FIG. 1B is a schematic plan view of an optical fingerprint recognition sensor according to the inventive concept;

FIG. 2A is a cross-sectional view of an optical fingerprint recognition sensor according to an embodiment of the inventive concept;

FIG. 2B is a view for explaining an operation of the optical fingerprint recognition sensor according to an embodiment of the inventive concept;

FIG. 3A is a cross-sectional view of an optical fingerprint recognition sensor according to another embodiment of the inventive concept;

FIG. 3B is a view for explaining an operation of the optical fingerprint recognition sensor according to an embodiment of the inventive concept; and

FIG. 4 is a view for explaining a wavelength band and intensity of light reflected by a ridge and valley.

### DETAILED DESCRIPTION

Advantages and features of the present invention, and implementation methods thereof will be clarified through following embodiments described with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Further, the present invention is only defined by scopes of claims. Like reference numerals refer to like elements throughout.

In the following description, the technical terms are used only for explaining a specific exemplary embodiment while not limiting the inventive concept. In this specification, the terms of a singular form may comprise plural forms unless specifically mentioned. The meaning of ‘comprises’ and/or ‘comprising’ specifies a component, a step, an operation and/or an element does not exclude other components, steps, operations and/or elements.

Hereinafter, embodiments of the inventive concept will be described in detail.

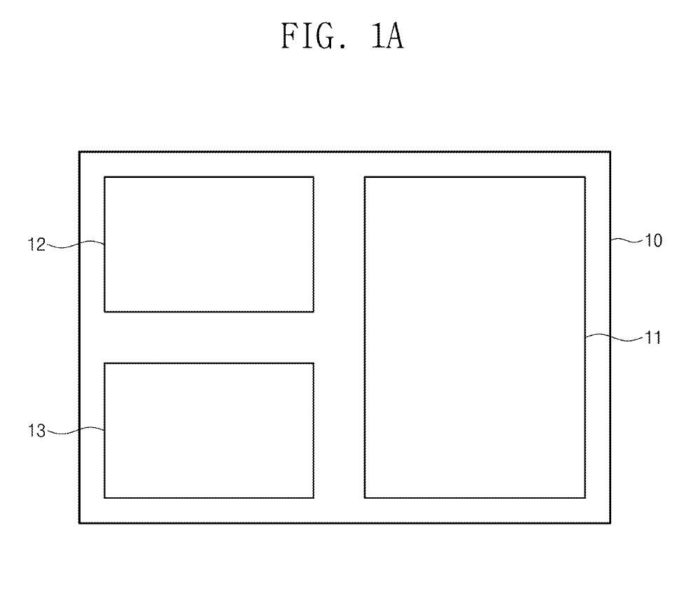

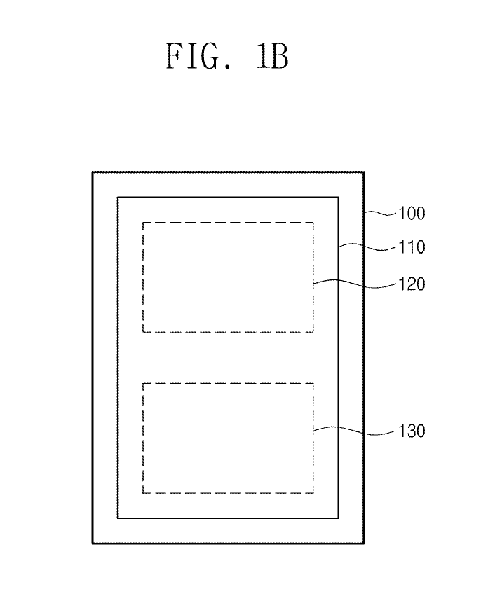

FIG. 1A is a schematic plan view of an optical fingerprint recognition sensor according to a comparative example of the inventive concept, and FIG. 1B is a schematic plan view of an optical fingerprint recognition sensor according to the inventive concept.

Referring to FIG. 1A, an optical fingerprint recognition sensor 10 according to the comparative example of the inventive concept may include a light emitting unit 11, a light receiving unit 12, and a control unit 13. The light receiving unit 12 and the control unit 13 may be disposed to be horizontally spaced apart from the light emitting unit 11. Thus, the optical fingerprint recognition sensor 10 has to have a planar area on which the light emitting unit 11, the light receiving unit 12, and the control unit 13 are disposed.

Referring to FIG. 1B, an optical fingerprint recognition sensor 100 according to the inventive concept may include a light emitting unit 110, a light receiving unit 120, and a control unit 130. The light receiving unit 120 and the control unit 130 may be disposed below the light emitting unit 110. That is to say, the light receiving unit 120 and the control unit 130 may vertically overlap the light emitting unit 110. In this case, the light emitting unit 110 may be transparent on the whole. As described above, the optical fingerprint recognition sensor 100 according to the inventive concept may have a planar area required for integrating the light emitting unit 110, the light receiving unit 120, and the control unit 130. Here, the planar area of the optical fingerprint recognition sensor 100 according to the inventive concept may be less than that of the optical fingerprint recognition sensor 10 according to the comparative example of the inventive concept. Thus, the optical fingerprint recognition sensor 100 according to the inventive concept may have integration and resolution, which are greater than those of the optical fingerprint recognition sensor 10 according to the comparative example of the inventive concept.

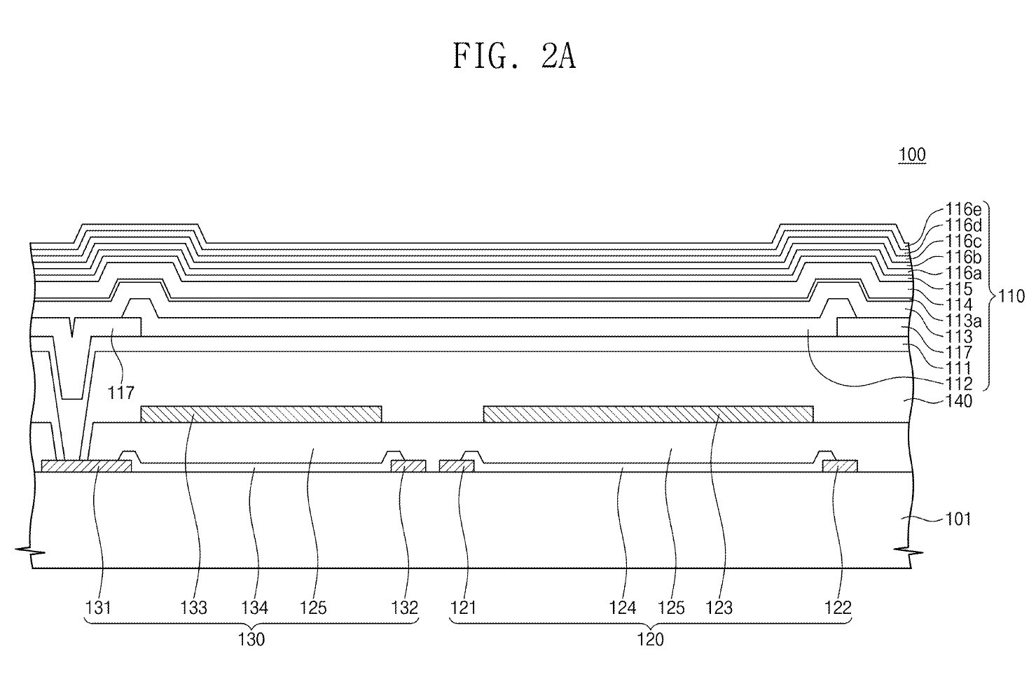

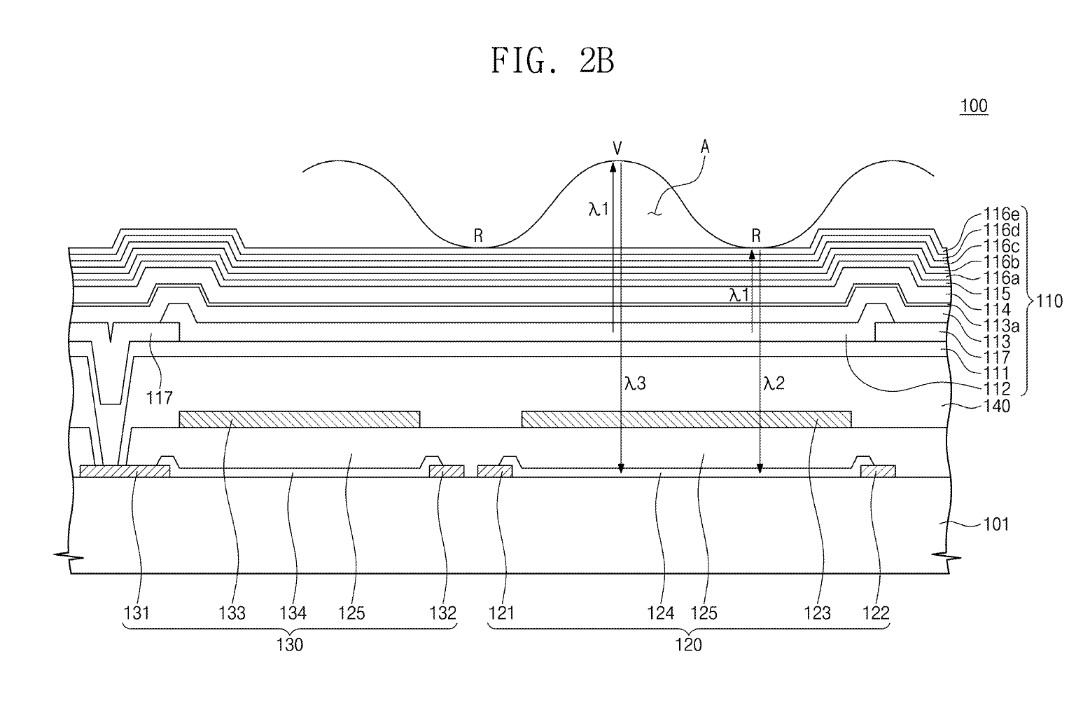

FIG. 2A is a cross-sectional view of an optical fingerprint recognition sensor according to an embodiment of the inventive concept.

Referring to FIG. 2A, the optical fingerprint recognition sensor 100 may include a substrate 101, a light emitting unit 110, a light receiving unit 120, a control unit 130, and a first insulation layer 140. The light receiving unit 120 and the control unit 130 may be disposed on the substrate 101. The first insulation layer 140 may be disposed on the light receiving unit 120 and the control unit 130. The light emitting unit 110 may be disposed on the first insulation layer 140.

The light receiving unit 120 may include a first source electrode 121, a first drain electrode 122, a first gate electrode 123, an optically active layer 124, and a second insulation layer 125. The optically active layer 124 may be disposed between the first source electrode 121 and the first drain electrode 122. The optically active layer 124 may include an photoreactive material. The second insulation layer 125 may be provided to cover the first source electrode 121, the first drain electrode 122, and the optically active layer 124. The first gate electrode 123 may be disposed on the second insulation layer 125. The light receiving unit 120 may receive light reflected by a fingerprint.

The control unit 130 may include a second source electrode 131, a second drain electrode 132, a second gate electrode 133, an active layer 134, and the second insulation layer 125. The active layer 134 may be disposed between the second source electrode 131 and the second drain electrode 132. The second insulation layer 125 may be provided to cover the second source electrode 131, the second drain electrode 132, and the active layer 134. The second gate electrode 133 may be disposed on the second insulation layer 125. The control unit 130 may control operations of the light receiving unit 120 and the light emitting unit 110.

The light emitting unit 110 may include a first electrode layer 111, an organic layer 112, a second electrode layer 113, a capping layer 114, a reflection layer 115, first to fifth encapsulation layers 116a, 116b, 116c, 116d, and 116e, and a bank 117. The first electrode layer 111, the organic layer 112, the second electrode layer 113, the capping layer 114, the reflection layer 115, and first to fifth encapsulation layers 116a, 116b, 116c, 116d, and 116e may be sequentially laminated on the first insulation layer 140. The light emitting unit 110 may be a transparent on the whole.

The first electrode layer 111 may be a positive electrode. The first electrode layer 111 may include a material having high conductivity and a high work function. The first electrode layer 111 may include transparent conductive oxide. For example, the first electrode layer 111 may include indium tin oxide, indium zinc oxide, indium gallium zinc oxide, fluorine zinc oxide, gallium zinc oxide, tin oxide, or zinc oxide.

Although not shown, the organic layer 112 may include a hole transport layer, a light emitting layer, and an electron transport layer. The hole transport layer, the light emitting layer, and the electron transport layer may be sequentially laminated on the first electrode layer 111. The hole transport layer may contribute to injection and transport of holes between the first electrode layer 111 and the light emitting layer. The light emitting layer may generate blue light, green light, or white light. The light emitting layer may include a fluorescent emission material or a phosphorescent emission material. The electron transport layer may contribute to injection and transport of electrons between the second electrode layer 113 and the light emitting layer. The organic layer 112 may receive the holes and the electrons from the first electrode layer 111 and the second electrode layer 113 to emit light.

The bank 117 may be disposed on a side surface of the organic layer 112. A planar area of the organic layer 112 may be determined by the bank 117. That is to say, a top surface of the first electrode layer 111 may be covered by the organic layer 112 and the bank 117. The bank 117 may include an organic material.

The second electrode layer 113 may be a negative electrode. The second electrode layer 113 may include a material having high conductivity and a low work function. For example, the second electrode layer 113 may include silver (Ag). For example, the second electrode layer 113 may have a thickness of about 15 nm to about 20 nm. The second electrode layer 113 may be transparent. The second electrode layer 113 may include a metal thin film layer 113a. The metal thin film layer 113a may be transparent. For example, the metal thin film layer 113a may include aluminum (Al). For example, the metal thin film layer 113a may have a thickness of about 1.3 nm to about 1.7 nm.

The capping layer 114 may include a dielectric. For example, the capping layer 114 may include silicon oxide or silicon nitride. The capping layer 114 may have a thickness that is relatively thicker than that of the reflection layer 115. For example, the capping layer may have a thickness of about 10 nm to about 1 μm.

The reflection layer 115 may include silver (Ag). For example, the reflection layer 115 may have a thickness of about 15 nm to about 20 nm.

Light emitted from the organic layer 112 may be reflected by the reflection layer 115 and the metal thin film layer 113a of the second electrode layer 113. The light may repeatedly pass through the capping layer 114 while reflected by the reflection layer 115 and the metal thin film layer 113a of the second electrode layer 113. Light having a specific wavelength band may be enhanced in intensity, and light having other wavelength bands may be weakened in intensity due to the repeated reflection. Only the light having the specific wavelength band, which is enhanced in intensity, may pass through the reflection layer 115. Also, light emitted from the organic layer 112 without having directivity may be adjusted in path in the vertical direction while passing through the reflection layer 115. As described above, a strong micro cavity effect may be generated by the reflection layer 115, the metal thin film layer 113a of the second electrode layer 113, and the capping layer 114. Thus, out coupling efficiency of the light emitting unit 110 may be improved.

The first to fifth encapsulation layers 116a, 116b, 116c, 116d, and 116e may have refractive indexes different from each other. For example, each of the first, third, and fifth encapsulation layers 116a, 116c, and 116e may have a relatively low refractive index, and the second and fourth encapsulation layers 116b and 116d may have a relatively high refractive index. That is to say, the encapsulation layers having the low refractive index and the encapsulation layers having the high refractive index may be alternately laminated. In this case, each of the first, third, and fifth encapsulation layers 116a, 116c, and 116e may include silicon oxide or fluorine magnesium, and the second and fourth encapsulation layers 116b and 116d may include titanium oxide, zinc sulfide, cerium oxide, aluminum oxide, zirconium oxide, and the like. For another example, each of the first, third, and fifth encapsulation layers 116a, 116c, and 116e may have a relatively high refractive index, and the second and fourth encapsulation layers 116b and 116d may have a relatively low refractive index. The first to fifth encapsulation layers 116a, 116b, 116c, 116d, and 116e may be adequately adjusted in thickness. The encapsulation layers having the low refractive index and the encapsulation layers having the high refractive index may be alternately laminated to increase in micro cavity effect of light passing through the first to fifth encapsulation layers 116a, 116b, 116c, 116d, and 116e. Although the five encapsulation layers 116a, 116b, 116c, 116d, and 116e are illustrated in the drawing, the embodiment of the inventive concept is not limited to the number of encapsulation layers.

FIG. 2B is a view for explaining an operation of the optical fingerprint recognition sensor according to an embodiment of the inventive concept.

Referring to FIG. 2B, the control unit 130 may control the light emitting unit 110 to emit light from the organic layer 112. The light emitted from the organic layer 112 may be enhanced in intensity at a specific wavelength band and may pass through the reflection layer 115 in the vertical direction. Then, the light may pass through the first to fifth encapsulation layers 116a, 116b, 116c, 116d, and 116e and then be incident into the fingerprint. The light may be incident into a ridge R and a valley V.

Since the light incident into the ridge R is reflected just by the ridge R contacting the light emitting unit 110, a peak wavelength λ1 of the light emitted from the light emitting unit 110 and a peak wavelength λ2 of the light reflected by the ridge R may be the same. Since the light incident into the valley V is emitted from the light emitting unit 110 to pass through an air layer A and then be reflected by the valley V, the peak wavelength λ1 of the light emitted from the light emitting unit 110 and a peak wavelength λ3 of the light reflected by the valley V may be different from each other. That is to say, the peak wavelength λ2 of the light reflected by the ridge R and the peak wavelength λ3 of the light reflected by the valley V may be different from each other. For example, the peak wavelength λ3 of the light reflected by the valley V may be greater than the peak wavelength λ2 of the light reflected by the ridge R. This may be affected by a refractive index of the air layer A. For example, each of the peak wavelength λ1 of the light emitted from the light emitting unit 110 and the peak wavelength λ2 of the light reflected by the ridge R may be about 453 nm, and the peak wavelength λ3 of the light reflected by the valley V may be about 487 nm. As described above, the peak wavelength may be a wavelength of light having the largest intensity in the wavelength band of the light.

The light reflected by the ridge R and the valley V may pass through the transparent light emitting unit 110 and then be incident into the light receiving unit 120. The optically active layer 124 of the light receiving unit 120 may include a photoreactive material. Thus, the optically active layer 124 may generate current according to the incident light. The magnitude of the current generated by the optically active layer 124 may vary according to the wavelength band and the light intensity of the incident light. The photoreactive material contained in the optically active layer 124 may be adequately selected to adjust the magnitude of the current generated when light having a specific wavelength band and a specific light intensity is incident. When the magnitude of the current generated by the optically active layer 124 exceeds a specific value, the light receiving unit 120 may be set to recognize the light. That is to say, the light receiving unit 120 may be set to receive light having a specific wavelength band and a specific light intensity. For example, the light receiving unit 120 may be set to receive the light reflected by the ridge R. Thus, whether the ridge R is disposed on the light receiving unit 120 may be determined according to whether the light receiving unit 120 receives light. For example, the light receiving unit 120 may be set to receive the light reflected by the valley V. Thus, whether the valley V is disposed on the light receiving unit 120 may be determined according to whether the light receiving unit 120 receives light. As described above, the light receiving unit 120 may be set to receive the light reflected by the ridge R or the valley V to recognize the position of the ridge R or the valley V, thereby recognizing the shape of the fingerprint.

The fingerprint recognition sensor 100 may be adjusted in optical path in the vertical direction by the reflection layer 115, the metal thin film layer 113a of the second electrode layer 113, and the capping layer 114. Thus, the fingerprint recognition sensor 100 may reduce an interference of the light reflected by the ridge R and the valley V to realize high resolution.

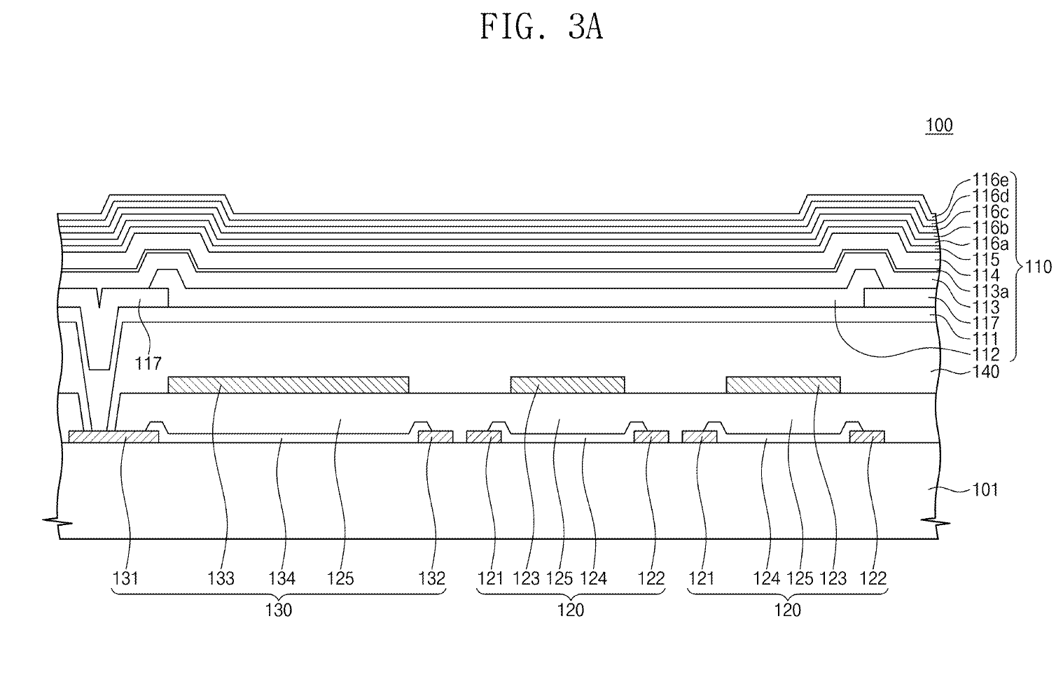

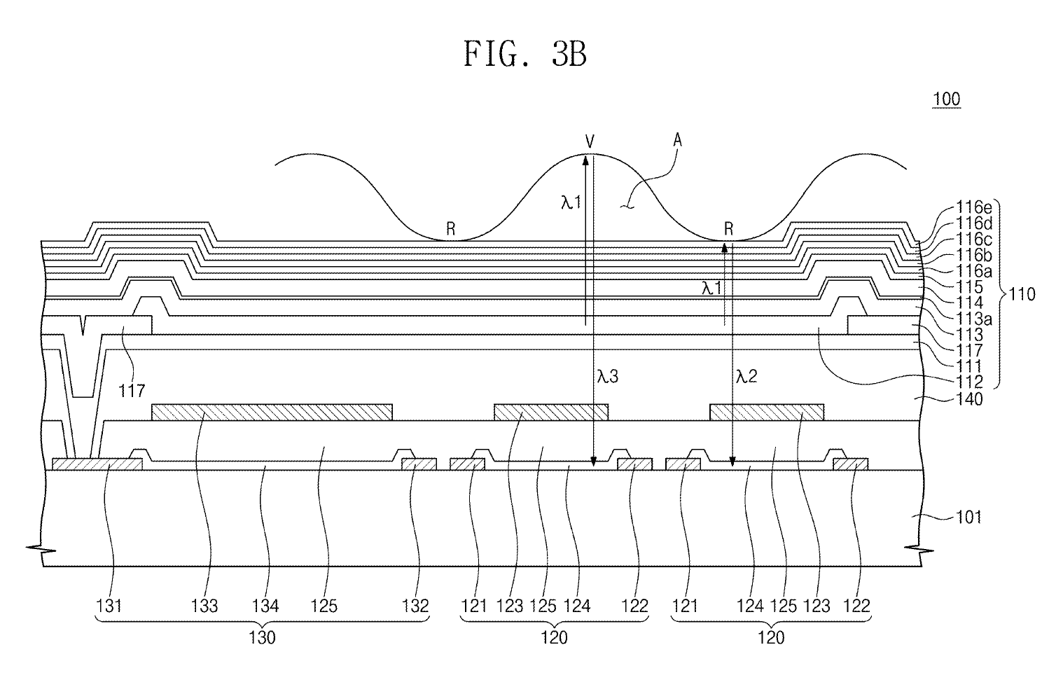

FIG. 3A is a cross-sectional view of an optical fingerprint recognition sensor according to another embodiment of the inventive concept.

An optical fingerprint sensor according to another embodiment of the inventive concept is the same as or similar to the optical fingerprint sensor according to the foregoing embodiment of the inventive concept except for features to be described below.

Referring to FIG. 3A, an optical fingerprint sensor 100 may include two light receiving units 120. Although the two light receiving units 120 are illustrated in the drawing, the embodiment of the inventive concept is not limited to the number of light receiving units 120. Each of the light receiving units 120 may include a first source electrode 121, a first drain electrode 122, a first gate electrode 123, an optically active layer 124, and a second insulation layer 125.

FIG. 3B is a view for explaining an operation of the optical fingerprint recognition sensor according to an embodiment of the inventive concept.

An operation of the optical fingerprint sensor according to another embodiment of the inventive concept is the same as or similar to that of the optical fingerprint sensor according to the foregoing embodiment of the inventive concept except for features to be described below.

Referring to FIG. 3B, the two light receiving units 120 may be set to receive light having different wavelength bands and light intensities, respectively. For example, the right light receiving unit 120 may be set to receive the light reflected by the ridge R, and the left light receiving unit 120 may be set to receive the light reflected by the valley V. Thus, the positions of the ridge R and valley V may be recognized according to whether each of the light receiving units receives the light to recognize the shape of the fingerprint.

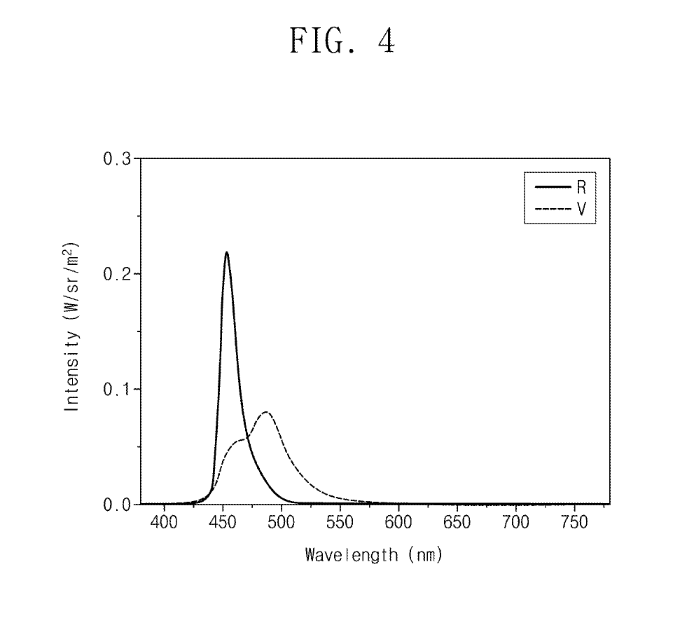

FIG. 4 is a view for explaining a wavelength band and intensity of light reflected by a ridge and valley.

Referring to FIG. 4, when the optical fingerprint recognition sensor according to the inventive concept operates, examples of the wavelength bands and the light intensities of the light reflected by the ridge R and the valley V may be confirmed. As illustrated in the drawing, the light reflected by the ridge R may have a peak wavelength of about 453 nm, and the light reflected by the valley V may have a peak wavelength of about 487 nm.

In the fingerprint recognition sensor according to the inventive concept, the light receiving unit and the control unit may vertically overlap the light emitting unit to realize the high integration and resolution.

In the fingerprint recognition sensor according to the inventive concept, the optical path may be adjusted in the vertical direction by the reflection layer, the metal thin film layer of the second electrode layer, and the capping layer to reduce the interference of the light reflected from the ridge and the valley of the fingerprint, thereby realizing the high resolution.

Although the embodiment of the inventive concept is described with reference to the accompanying drawings, those with ordinary skill in the technical field of the inventive concept pertains will be understood that the present disclosure can be carried out in other specific forms without changing the technical idea or essential features. Thus, the above-disclosed embodiments are to be considered illustrative and not restrictive.

What is claimed is:

1. An optical fingerprint recognition sensor comprising:
a transparent light emitting unit configured to emit light to a fingerprint;
a light receiving unit disposed below the light emitting unit to vertically overlap the light emitting unit and configured to receive light reflected by the fingerprint; and
a control unit disposed below the light emitting unit to vertically overlap the light emitting unit and configured to control the light emitting unit and the light receiving unit,
wherein the light emitting unit comprises an organic layer.

2. The optical fingerprint recognition sensor of claim 1, wherein the light emitting unit further comprises:
a metal thin film layer on the organic layer;
a capping layer on the metal thin film layer; and
a reflection layer on the capping layer,
wherein the capping layer has a thickness greater than that of the reflection layer.

3. The optical fingerprint recognition sensor of claim 2, wherein light emitted from the organic layer is repeatedly reflected between the metal thin film layer and the reflection layer.

4. The optical fingerprint recognition sensor of claim 2, wherein the reflection layer comprises silver (Ag).

5. The optical fingerprint recognition sensor of claim 2, wherein the reflection layer has a thickness of about 15 nm to about 20 nm, and
the capping layer has a thickness of about 10 nm to about 1 μm.

6. The optical fingerprint recognition sensor of claim 2, wherein the light emitting unit further comprises:
a first electrode below the organic layer; and
a second electrode on the organic layer,
wherein the second electrode comprises the metal thin film layer.

7. The optical fingerprint recognition sensor of claim 1, wherein the light emitting unit further comprising a plurality of encapsulation layers, and
the encapsulation layer having a low refractive index and the encapsulation layer having a high refractive index are alternately laminated.

8. The optical fingerprint recognition sensor of claim 1, wherein the light receiving unit receives light reflected by a ridge of the fingerprint.

9. The optical fingerprint recognition sensor of claim 1, wherein the light receiving unit is provided in plurality, and
the plurality of light receiving units receive light reflected by a ridge of the fingerprint and light reflected by a valley of the fingerprint, respectively.

10. The optical fingerprint recognition sensor of claim 6, wherein each of the second electrode and the metal thin film layer is transparent.
